(19) United States
(12) Patent Application Publication
(10) Pub. No.: US 2008/0007343 A1
(43) Pub. Date: Jan. 10, 2008

(54) Tuning A Trans-Impedance Amplifier

(75) Inventor: Brad Anthony NATZKE, Rochester, MN (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: JDS Uniphase Corporation, Milpitas, CA (US)

(21) Appl. No.: 11/456,287

(22) Filed: Jul. 10, 2006

(51) Int. Cl. H03F 3/08

(52) U.S. Cl. 330/308

(57) ABSTRACT

A trans-impedance amplifier has a front-end circuit including a transistor and collector resistor for setting the open-loop gain of the feedback circuit. The collector resistor, when connected directly to the power supply, has a secondary function of defining the current through the gain transistor, affecting second-order characteristics. A current source is added between the collector resistor and power supply providing a means by which several outside factors can be mitigated, e.g the current source can take over duties for determining/defining the current for the gain transistor, thereby enabling the choice of collector resistor for setting the open-loop gain separate from the current for the gain transistor.

### CROSS-REFERENCE TO RELATED APPLICATIONS

The present invention claims no priority.

### TECHNICAL FIELD

The present invention relates to a circuit for tuning a trans-impedance amplifier for a photodiode, and in particular to the use of a controllable current source for tuning out external effects, e.g. changes in power supply voltage or temperature, on a trans-impedance amplifier.

### BACKGROUND OF THE INVENTION

With reference to FIG. 1, a conventional TIA circuit, generally indicated at 1, converts the current IPD exiting a photodiode 2, into an output voltage VOUT. The photodiode current IPD, which enters the TIA circuit 1 at an input terminal 3, includes both a DC component and an AC component. The AC component, which carries the information, must be maintained and sent down an amplification chain 4 to final receiving equipment (not shown), while the DC component should be ignored and if possible eliminated, since many front end unit inputs are not designed to tolerate much more than 10 uA. A feedback circuit, generally indicated at 5, removes the DC component by means of negative feedback implemented by a feedback amplifier 6/low pass filter (i.e. Capacitor 7) and a bypass transistor 8 combination. The feedback amplifier 6/low pass filter 7 has gain, and removes the AC component of a voltage feedback signal V_{FB}, leaving only a DC component V_{FBDC}. The capacitor 7 is used to set the low-frequency cutoff that the TIA circuit 1 requires. The bypass transistor 8 takes that DC component V_{FBDC} of the voltage feedback signal V_{FB} and generates a DC current I_{FBDC} in the collector 9, which by the action of negative feedback equals the incoming DC current I_{PDDC} from the photodiode 2. Accordingly, the DC component I_{PDDC} is removed from the incoming signal IPD and passed to the ground GRND through the emitter 10 of the bypass transistor 8.

In practice, the TIA circuit can be mounted on a printed circuit board, which forms part of an opto-electronic device, such as a transceiver. The opto-electronic device has an optical connector for coupling to an optical waveguide, e.g. fiber, and an electrical connector for electrically connecting the device to a host computer system. The opto-electronic device can have control and monitoring circuitry; however, the host computer system can also provide control and monitoring systems and functions.

A conventional trans-impedance amplifier front end circuit 11, illustrated in greater detail in FIG. 2, includes an AC circuit portion 22 having a first amplifying transistor 23 (Q), a first collector resistor 24 (R_{c}) generally 200 Ohms, which works against the emitter resistance of the first transistor 23 to set the open loop gain A (generally between 10-20), and a first feedback resistor 25 (R_{fb}) generally 500 ohms. The equation describing the amplifier II is Vₒᵤₜ/I_{PD}=A/(1+A/R_{fb}). When the open loop gain (A) is large enough (e.g.>10), the overall gain is approximated by V_{OUT}=I_{PD}×R_{fb}. A complimentary (DC) circuit 26, which includes a second amplifying transistor 28 (Q_dc), a second feedback resistor 29 (Rfb_dc), a DC output voltage (out_dc), and a second collector resistor 30 (Rc_dc), is added to provide a reference voltage to the following amplification stages that tracks process variation and environmental effects, such as temperature and power supply voltage changes. The DC component of the out_dc is substantially the same as the out_ac signal over most environmental conditions; however, the DC component is not the focus of the invention.

The high-speed performance of the trans-impedance front end circuit 11 is sensitive to changes in power supply voltage vdda 27 because the output voltage out_ac is ground referenced. Assuming that the DC current flowing through feedback resistor R_{fb} 25 is negligible, then the DC component of the output voltage out_ac will be equal to the base voltage V_{be} of the first transistor 23, independent of power supply voltage vdda from the power supply 27. When the power supply voltage (vdda) increases, the current through the first transistor 23 ([vdda-out_ac]/Rc) increases. The same is true for the DC circuit 22. Changes in the power supply voltage vdda causes the operating conditions of the first and second amplifying transistors 23 and 28 (Q and Q_dc) to vary, which in turn causes undesirable variations in performance. Not only does the open loop gain of the amplifier 11 increase with a larger power supply voltage vdda (smaller emitter resistance of the first and second transistors 23 and 28 due to the increased current), but the high-frequency performance of the first transistor 23 changes with changing bias current. Both of these phenomena are generally seen as second-order effects, but still significant to improving real-world performance. The present invention addresses second-order high-speed performance improvements that can be achieved in a trans-impedance amplifier front-end circuit.

Typically, the design of a trans-impedance amplifier front end circuit involves a trade-off, i.e. the Rc collector resistor 24 sets the open loop gain, but it also defines the current running through the first transistor 23. The balance is often very difficult to get correct because of changes in the power supply voltage vdda. Often times, the collector resistor 24 Rc, required for the open loop gain, is small (200 Ohms), which for a power supply voltage on the upper end of it's allowable range causes a large current e.g. 10 mA, to flow through the first transistor 23 in which 2 mA would be desirable.

U.S. Pat. No. 6,404,281, issued Jun. 11, 2002 in the name of Kobayashi et al; U.S. Pat. No. 6,504,429, issued Jan. 7, 2003 to Kobayashi et al; and U.S. Pat. No. 6,771,132 issued Aug. 3, 2004 to Denoyer et al disclose improvements to TIA feedback circuits that include minimizing the upper limit of the low frequency cut off frequency; however, none of these references provide an adjustable current source for tuning out external effects on the trans-impedance amplifier

An object of the present invention is to overcome the shortcomings of the prior art by providing an adjustable current source that tunes out external effects on a trans-impedance amplifier.

### SUMMARY OF THE INVENTION

Accordingly, the present invention relates to a trans-impedance amplifier circuit, including a front-end circuit, for converting the variable input current signal into an output voltage; and

wherein the front-end circuit comprises:

an amplifier circuit with an open loop gain; and

a controllable current source device which generates a control current for mitigating unwanted effects.

### BRIEF DESCRIPTION OF THE DRAWINGS

The invention will be described in greater detail with reference to the accompanying drawings which represent preferred embodiments thereof, wherein:

FIG. 1 illustrates a conventional TIA amplifier circuit with feedback circuit;

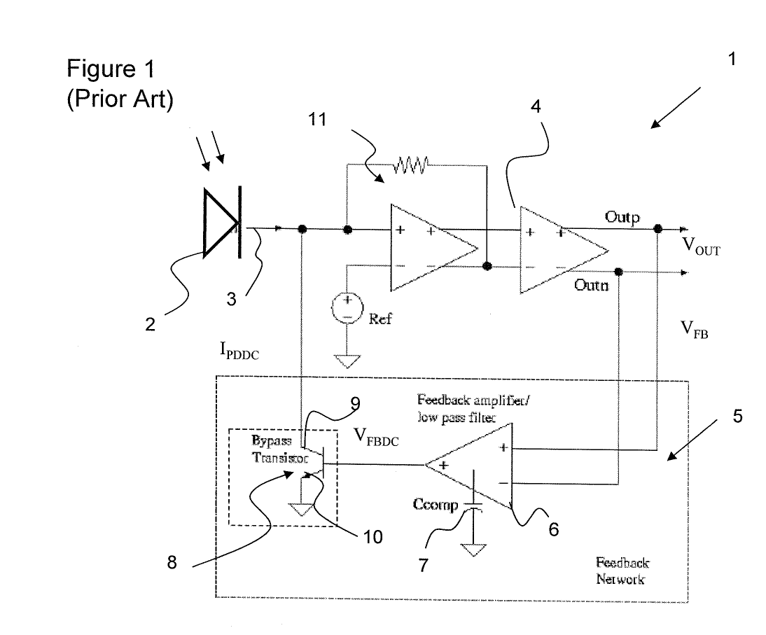

FIG. 2 illustrates a conventional TIA front end circuit;

FIG. 3 illustrates a TIA front end circuit according to the present invention;

FIG. 4 illustrates another embodiment of TIA front end circuit according to the present invention; and

FIG. 5 illustrates another embodiment of TIA front end circuit according to the present invention.

### DETAILED DESCRIPTION

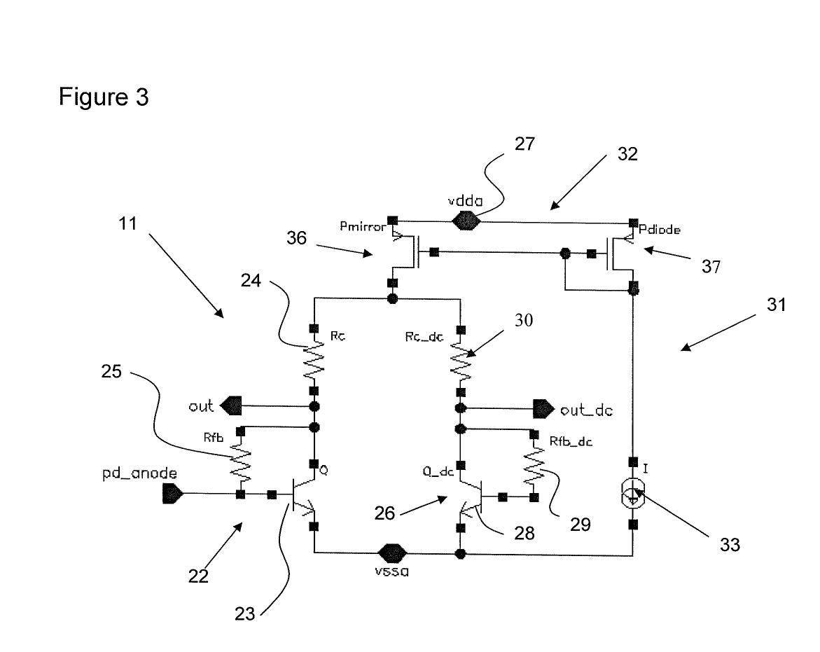

With reference to FIG. 3, by inserting a controlled current device 31, including a current mirror 32 (Pmirror) and a current source 33 (I) between the power supply 27 (Vdda) and the first collector resistor 24 of the trans-impedance front end circuit 11, the effect of power supply voltage variation on the performance of the front end circuit 11 can be minimized. The current mirror 32 comprises a third transistor 36 (Pmirror) and a fourth transistor 37 (Pdiode), which replicates the current, e.g. a portion or a multiple thereof, from the tunable current source 33 and generates a voltage in the collector resistance 24 (Rc). In effect, a virtual power supply node is created at the drain of the third transistor 36 that is more stable with respect to ground than the voltage Vdda from the power supply 27. If the power supply voltage Vdda increases, the voltage across the third transistor 36 increases by the same amount. The new equation describing the current in the first transistor 23 is I_{FT}=[virtual_supply-out_ac]/Rc. However, the current I_{FT}=Icurrentsource/2, assuming that the current mirror 32 is a 1:1 mirror. The division by 2 comes about because half of the current flows through each of the third and fourth transistors 36 and 37. Accordingly, the voltage virtual_supply=(Icurrentsource×Rc)/2+out_ac, wherein out_ac is effectively the base voltage V_{be} of the first transistor 23 and is ground referenced. In the illustrated embodiment of FIG. 3, the third and fourth transistors 36 and 37 are each a PFET; however, any similar device that can deliver a tunable, controllable current from the positive supply, negative supply, or ground (if the photodiode can tolerate reduced operating voltage) can be substituted.

There are other ways of accomplishing the controlled current source 31, but in accordance with the illustrated embodiment, you need a tunable current source 33 and a mirror 32, which present the current Icurrentsource to the front end circuit 11. The fourth transistor 37 Pdiode provides the control voltage that tells the current mirror transistor, i.e. the third transistor 36, Pmirror what current to deliver, which is fundamental current source construction. In use the fourth transistor 37 is the diode, i.e. the side that the reference current (Icurrentsource) enters, and the third transistor 36 is the mirror. If the third and fourth transistors 36 and 37 are identical, then the voltage across the diode, i.e. the fourth transistor 37, will generate the exact voltage necessary to control the mirror, i.e. the third transistor 36, to put out the same amount of current.

The present invention enables a designer to decouple the design aspects of the Rc collector resistor 24 into two components, i.e. separate the setting of the open loop gain A, from the desired amount of current I_{FT} running through the first transistor 23. The 2 mA desired bias current I_{FT} through the first and second transistors 23 and 28 can be set by the current source 33, and the open loop gain can be set by choice of the collector resistance Rc 24, in this case, 200 Ohms.

The embodiment described above is intended to cancel out unwanted power supply variation; however, a designer might also want to mitigate other second order circuit effects, including, but not limited to, temperature, received signal strength, and data rate, by tuning the characteristics of the current source 33. The emitter resistance of the first transistor 25 is temperature dependent, but the collector Rc resistor 24 may have no temperature coefficient, or the temperature coefficient of the collector resistor 24 may be in the opposite direction to the temperature coefficient of the transistor emitter resistance. Under these conditions, the open-loop gain of the front end circuit 11 will vary greatly from cold to hot temperatures. In these cases, the designer can construct Icurrentsource out of a mixture of currents that are flat with temperature and currents that are proportional to absolute temperature (PTAT) to arrive at a combination that will provide consistent open-loop gain over the designed temperature range. It is well known in the industry that currents of arbitrary temperature coefficient, positive or negative can be generated by adding and subtracting the right proportions of flat and PTAT currents. Therefore, a designer can tune the temperature performance of the front end circuit 11 to achieve any desired performance. A PTAT current may be appropriate for canceling out the decreasing emitter resistance with temperature. A different temperature profile might be desirable for canceling out the temperature coefficient of the collector Rc resistors 24 and 30. This can be done internal to a control chip provided with the TIA PCB at the time of fabrication as temperature changes in circuit components are generally well modeled. A designers simulations will show the temperature dependence of the open-loop gain, for instance, which can then be mitigated with the appropriate recipe of flat, PTAT and NTAT currents built on-chip. A temperature monitor can also be provided for sending temperature measurements to an external control processor, which tunes the current source 33 accordingly. The latter method is possible, but more expensive to implement and generally not necessary.

Alternatively, if the open loop gain A is too high at cold temperatures, and too low at hot temperatures, the current (I) from the current source 33 can be made proportional to absolute temperature (PTAT) so that more current could be supplied at hot and less at the cold condition, to ensure the open loop gain A is maintained substantially constant, e.g. ±5%. As above, a temperature monitor can be provided for sending temperature measurements to a control processor, which tunes the current source 33 accordingly. Alternatively, a temperature profile can be predetermined and saved in the control processor to tuning the current source 33.

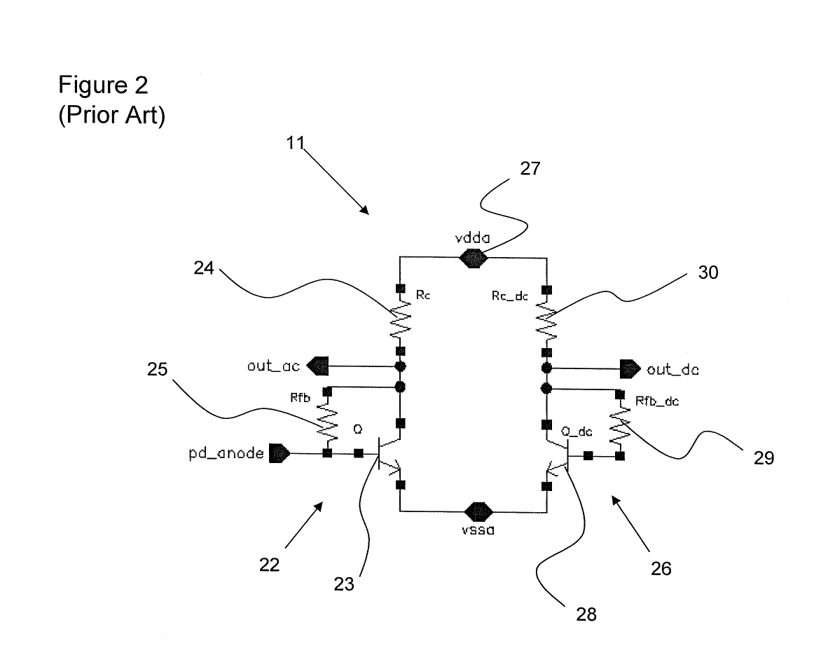

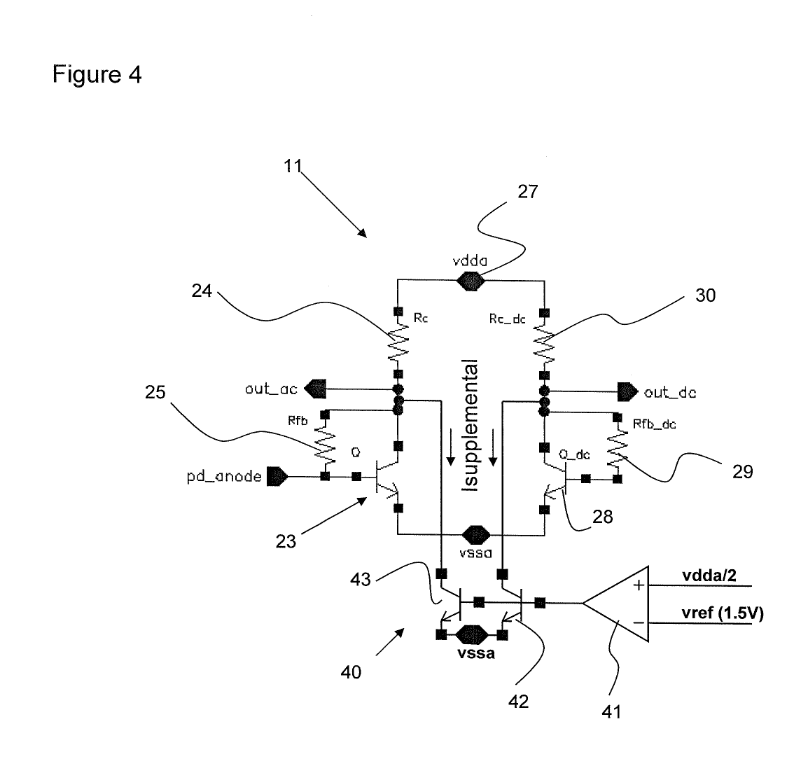

In an alternate embodiment, shown in FIG. 4, a current source 40 can be used to pull current (Isupplemental) from the ac_out and dc_out to the ground where the collector resistors 24 and 30 are directly connected to the power supply as in FIG. 2. The extra current from the current source superimposes an additional voltage drop across the desired collector resistor 24 Rc (e.g. 200 Ohms). Accordingly, one can get the benefit of a small collector resistor 24 Rc and control over the gain transistor bias current. For a power supply variation of 600 mV and a collector resistance of 200 Ohms, a maximum additional current Iₛᵤₚₚₗₑₘₑₙₜₐₗ of 3 mA would be required. The main difficulty with this approach is that a feedback loop is required to sense what the power supply voltage Vdda is so that the correct amount of current can be drawn through the collector resistor Rc 24. In FIG. 4, an opamp 41 is used to sense a voltage that is half of the power supply (vdda/2) and compare it to a voltage reference, in this case 1.5V. A 1.5V reference voltage assumes that the minimum power supply voltage will be 3.0V, so that current will always be drawn through transistors 42 and 43. The opamp 41 drives an NPN transistor 42, though any other compatible device can be substituted. If the supply vdda is high, current closer to the maximum 3 mA in the example above is drawn. If the supply vdda is low, Isupplemental closer to 0 mA is drawn.

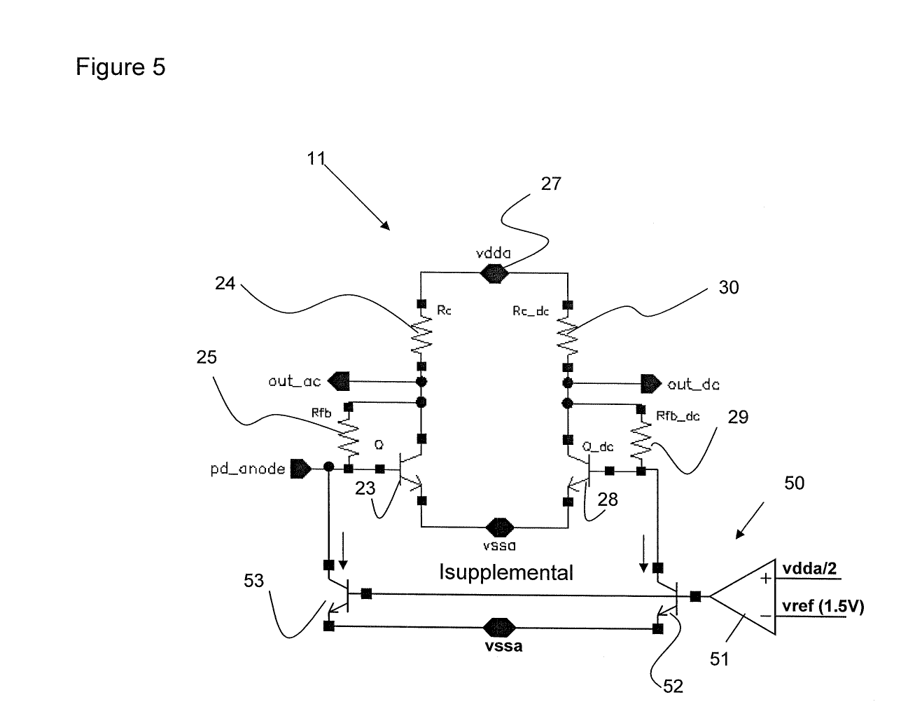

In another alternate embodiment similar to the one discussed above with reference to FIG. 4, the current Isupplemental is instead pulled by a current source 50 from the pd_anode and inserted between the pd_anode and ground and pulls an appropriate amount of DC bias current through a combination of the feedback resistor 25 (Rfb) and the collector resistor 24 (Rc), i.e. bypassing the first transistor 23 Q. This approach requires less current because the feedback resistor 25 is generally much larger than the collector resistor Rc 24. The extra current will superimpose the appropriate additional voltage drop on both the collector resistor 24 (Rc) the feedback resistor 25 (Rfb) to make the transistor current in the first transistor 23 consistent with the aforementioned example above. In FIG. 5, an opamp 51 is used to sense a voltage that is half of the power supply (vdda/2) and compare it to a voltage reference, in this case 1.5V. A 1.5V reference voltage assumes that the minimum power supply voltage will be 3.0V, so that current will always be drawn through transistors 52 and 53. The opamp 51 drives an NPN transistor 52, though any other compatible device can be substituted. As above, if the supply vdda is high, current closer to the maximum 3 mA in the example above is drawn. If the supply vdda is low, a supplemental current (Iₛᵤₚₚₗₑₘₑₙₜₐₗ) closer to 0 mA is drawn.

For a power supply variation of 600 mV, collector resistor 24 of 200 Ohms and feedback resistor 25 of 400 Ohms, the current required would be about 1 mA, ⅓ of the previous embodiment. This implementation suffers one key shortcoming for high-speed applications: the pd_anode node is highly sensitive to capacitance. Each circuit element connected to pd_anode adds capacitance and worsens the performance.

We claim:

1. A photodetector amplifier circuit comprising:
a photodetector for converting an optical signal into a variable input current signal having AC and DC components; and
a trans-impedance amplifier circuit, including a front-end circuit, for converting the variable input current signal into an output voltage; and
wherein the front-end circuit comprises:
an amplifier circuit with an open loop gain; and
a controllable current source device which generates a control current for mitigating unwanted effects.

2. The photodetector amplifier circuit according to claim 1, wherein the amplifier circuit comprises:
a first gain transistor providing the open-loop gain and a first gain transistor resistance;
a power supply for generating a supply voltage;
a first resistance connected between the power supply and the transistor for generating a transistor current for the first gain transistor, and for setting the gain of the first gain transistor along with the resistance of the first gain transistor.

3. The photodetector amplifier circuit according to claim 2, wherein the controllable current source changes with fluctuations in the power supply ensuring that the transistor current is insensitive to fluctuations in the power supply, thereby maintaining a desired amount of current passed to the first gain transistor.

4. The photodetector amplifier circuit according to claim 2, wherein at least one of the first resistance and the resistance of the first gain transistor change with temperature; and wherein the controllable current source is tuned to at least partially compensate for the changes therein.

5. The photodetector amplifier circuit according to claim 4, further comprising control means for tuning the controllable current source; wherein the controllable current source is tuned based on a predetermined temperature profile saved in the control means.

6. The photodetector amplifier circuit according to claim 4, further comprising:
control means for tuning the controllable current source; and
temperature monitoring means for providing temperature measurements to the control means;
wherein the controllable current source is tuned based on the temperature measurements.

7. The photodetector amplifier circuit according to claim 2, wherein the controllable current source comprises:
an adjustable current source for generating a current source current; and
a current mirror for providing at least a portion of the current source current to the amplifier circuit;
wherein the controllable current source is electrically connected between the power supply and the front end circuit.

8. The photodetector amplifier circuit according to claim 2, wherein the controllable current source comprises a current source pulling additional current through the first resistance for creating a voltage drop on the first resistance and raising a DC voltage across the first resistance to define the transistor current in the first gain transistor.

9. The photodetector amplifier circuit according to claim 2, wherein the amplifier circuit further comprises a second resistance providing a feedback resistance electrically connected between a collector and a base of the first gain transistor; and wherein the controllable current source comprises a current source pulling additional current through the first and second resistances for creating a voltage drop on the first and second resistances and raising a DC voltage across the first and second resistances to define the transistor current in the first gain transistor.

10. The photodetector amplifier circuit according to claim 2, wherein current from the controllable current source is proportional to absolute temperature (PTAT), whereby more current is supplied at hot and less at cold temperatures to ensure the open-loop gain is maintained substantially constant.

11. The photodetector amplifier circuit according to claim 10, further comprising control means for tuning the controllable current source; wherein the controllable current source is tuned based on a predetermined temperature profile saved in the control means.

12. The photodetector amplifier circuit according to claim 10, further comprising:
control means for tuning the controllable current source; and
temperature monitoring means for providing temperature measurements to the control means;
wherein the controllable current source is tuned based on the temperature measurements.
